(19) United States
(12) Patent Application Publication
(10) Pub. No.: US 2017/0352639 A1
(43) Pub. Date: Dec. 7, 2017

(54) METHOD FOR PROTECTING BOND PADS FROM CORROSION

(71) Applicant: Knowles Electronics, LLC, Itasca, IL (US)

(72) Inventors: Peter V. Loeppert, Durand, IL (US); Michael Pedersen, Ashton, MD (US)

(73) Assignee: Knowles Electronics, LLC, Itasca, IL (US)

(21) Appl. No.: 15/171,881

(22) Filed: Jun. 2, 2016

(51) Int. Cl. H01L 23/00; B81C 1/00; H01L 21/78; B81B 7/00

(52) U.S. Cl. CPC H01L 24/48; B81B 7/007; B81C 1/00301; H01L 21/78; H01L 24/03; H01L 24/09; H01L 24/16; H01L 24/81; H01L 24/85; H01L 2224/48824; H01L 2224/48747; H01L 2224/48744; H01L 2224/48739; H01L 2224/48647; H01L 2224/48639; H01L 2224/48624; H01L 2224/48465; H01L 2224/4845; H01L 2224/05147; H01L 2224/05144; H01L 2224/05139; H01L 2224/05124; H01L 2224/04042; H01L 2224/0401; H01L 2224/03831; H01L 2224/0382; B81B 2201/0257; H01L 2224/48839; H01L 2224/48844; H01L 2224/85012; H01L 2224/851; H01L 2224/8534; H01L 2924/06; H01L 2924/0715; H01L 2924/1461; H01L 2924/14335

(57) ABSTRACT

Methods, systems, and apparatuses for preventing corrosion between dissimilar bonded metals. The method includes providing a wafer having a plurality of circuits, each of the plurality of circuits having a plurality of bond pads including a first metal; applying a coating onto at least the plurality of bond pads; etching a hole in the coating on each of the plurality of bond pads to provide an exposed portion of the plurality of bond pads; dicing the wafer to separate each of the plurality of circuits; die bonding each of the plurality of circuits to a respective packaging substrate; and performing a bonding process to bond a second, dissimilar metal to the exposed portion of each of the plurality of bond pads such that the second, dissimilar metal encloses the hole in the coating of each of the plurality of bond pads, thereby enclosing the exposed portion.

### BACKGROUND

The following description is provided to assist the understanding of the reader. None of the information provided or references cited is admitted to be prior art.

Bonding dissimilar metals in circuitry may lead to an increased risk of electrochemical corrosion in the presence of moisture. Circuitry with dissimilar bonded metals are traditionally hermetically sealed or the bonds between the dissimilar metals are covered with a glob top to eliminate moisture exposure.

### SUMMARY

In general, one aspect of the subject matter described in this specification can be embodied in methods for preventing corrosion between dissimilar bonded metals. The method includes providing a wafer having a plurality of circuits, each of the plurality of circuits having a plurality of bond pads including a first metal; applying a coating onto at least the plurality of bond pads; etching a hole in the coating on each of the plurality of bond pads to provide an exposed portion of the plurality of bond pads; dicing the wafer to separate each of the plurality of circuits; die bonding each of the plurality of circuits to a respective package substrate; and performing a bonding process to bond a second, dissimilar metal to the exposed portion of each of the plurality of bond pads such that the second, dissimilar metal encloses the hole in the coating of each of the plurality of bond pads, thereby enclosing the exposed portion.

In general, another aspect of the subject matter described in this specification can be embodied in a circuit for a device having packaging that is at least partially open to an external environment. The circuit includes a plurality of bond pads including a first metal, a coating at least partially covering each of the plurality of bond pads, and a plurality of bond structures including a second, dissimilar metal. The coating defines a plurality of holes. One of the plurality of holes is positioned to align with each of the plurality of bond pads, thereby providing an exposed portion of each of the plurality of bond pads. Each of the plurality of bond structures is attached to the exposed portion of a respective one of the plurality of bond pads such that the plurality of bond structures enclose the plurality of holes in the coating, thereby enclosing the exposed portion of each of the plurality of bond pads such that the plurality of bond pads are completely sealed off from the external environment by the coating and the plurality of bond structures.

In general, another aspect of the subject matter described in this specification can be embodied in a device. The device includes a packaging at least partially open to an external environment and a circuit die bonded to a packaging substrate of the packaging. The circuit includes a plurality of bond pads including a first metal, a coating at least partially covering each of the plurality of bond pads, and a plurality of bond structures including a second, dissimilar metal. The coating defines a plurality of holes. One of the plurality of holes is positioned to align with each of the plurality of bond pads, thereby providing an exposed portion of each of the plurality of bond pads. Each of the plurality of bond structures is attached to the exposed portion of a respective one of the plurality of bond pads such that the plurality of bond structures enclose the plurality of holes in the coating, thereby enclosing the exposed portion of each of the plurality of bond pads such that the plurality of bond pads are completely sealed off from the external environment by the coating and the plurality of bond structures.

The foregoing summary is illustrative only and is not intended to be in any way limiting. In addition to the illustrative aspects, embodiments, and features described above, further aspects, embodiments, and features will become apparent by reference to the following drawings and the detailed description.

### BRIEF DESCRIPTION OF THE DRAWINGS

The foregoing and other features of the present disclosure will become more fully apparent from the following description and appended claims, taken in conjunction with the accompanying drawings. Understanding that these drawings depict only several embodiments in accordance with the disclosure and are, therefore, not to be considered limiting of its scope, the disclosure will be described with additional specificity and detail through use of the accompanying drawings.

FIG. 1 is a detailed perspective view of a bond interface having a bond pad and a ball bond in accordance with various implementations.

FIG. 2 is a detailed perspective view of an interface between the bond pad and ball bond of FIG. 1 in accordance with various implementations.

FIG. 3 is a perspective view a device having a circuit with a plurality of bond interfaces in accordance with various implementations.

FIG. 4 is a perspective view of a bond pad having a coating in accordance with various implementations.

FIG. 5 is a detailed perspective view of the bond interface of FIG. 3 having a bond pad, a ball bond, and a coating in accordance with various implementations.

FIG. 6 is a detailed perspective view of an interface between the bond pad, the ball bond, and the coating of FIG. 5 in accordance with various implementations.

FIG. 7 is a flow diagram of a methods for preventing corrosion between dissimilar bonded metals in accordance with various implementations.

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and make part of this disclosure.

### DETAILED DESCRIPTION

According to an exemplary embodiment, systems, methods, and apparatuses for protecting bond pads from corrosion are disclosed herein. Electrochemical corrosion may occur between two dissimilar bonded metals in the presence of moisture (e.g., especially if halides such as chlorides, fluorides, etc. are also present). Traditionally, integrated circuits are hermetically packaged such that they are completely isolated from an external environment to prevent such corrosion. However, transducers such as microphones (e.g., of a microelectromechanical system (MEMS) device, etc.) cannot be hermetically sealed since such transducers need to be at least partially open to the external environment (e.g., to receive sound waves, etc.). Exposing such transducers to the external environment may increase the risk of electrochemical corrosion between the two dissimilar bonded metals. One solution to prevent and/or eliminate such corrosion may be to use a single metal such as gold, however using gold is not cost effective. Another solution to prevent and/or eliminate such corrosion may be to cover the dissimilar bonded metals with a glob top so as to eliminate moisture exposure. However, such a process has to be performed on an individual bond basis at the package level (e.g., per device, etc.) and is therefore not very cost effective. Further, glob tops may not be able to be used in MEMS microphones due to spacing restrictions as the spacing between the transducer and the bond pads may be too tight to accommodate the use of glob tops.

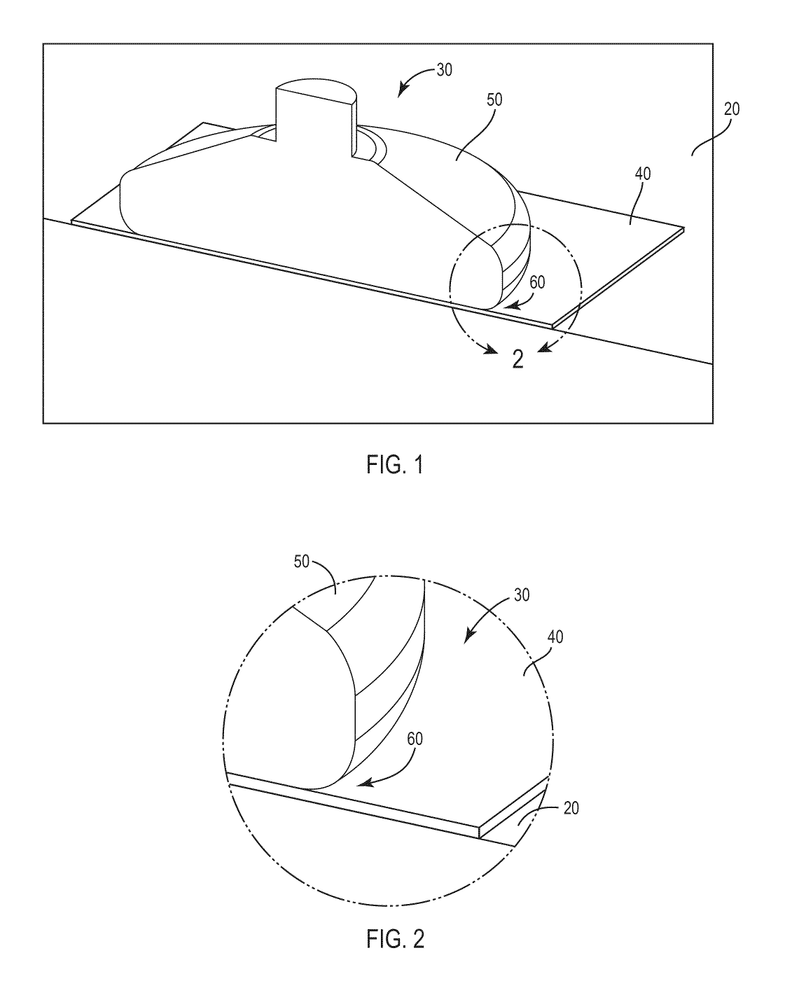

Referring now to FIGS. 1-2, a circuit, shown as circuit 20, includes a bond, shown as bond 30. As shown in FIG. 1-2, the bond 30 includes a pad, shown as bond pad 40, and a bond structure, shown as ball bond 50, with an interface, shown as bond interface 60, formed between the bond pad 40 and the ball bond 50. The bond pad 40 may include a first metal (e.g., aluminum, gold, copper, silver, etc.) and the ball bond 50 may include a second, dissimilar metal (e.g., aluminum, gold, copper, silver, etc.). Thus, the bond interface 60 between the bond pad 40 and the ball bond 50 may be susceptible to corrosion. Traditionally, the bond 30 is covered with a glob top and/or the circuit 20 is hermetically sealed from an external environment to prevent corrosion between the bond pad 40 and the ball bond 50. However, such solutions can be uneconomical and/or inefficient. For example the glob tops have to be applied at the package level rather than at a wafer level which can impact production efficiencies and cost. Further, such solutions may not be available for use with MEMS microphones since the transducers need to be open to the external environment such that they cannot be hermetically sealed and the internal spacing may be too tight to facilitate the use of glob tops.

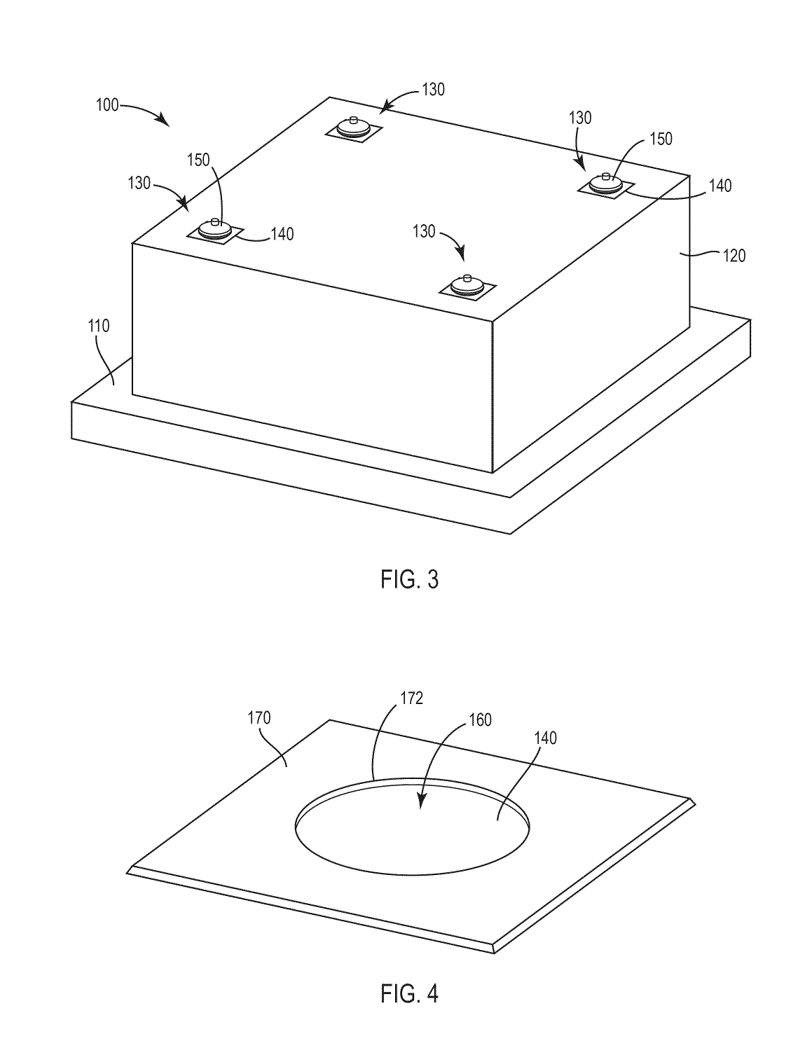

According to the exemplary embodiment shown in FIGS. 3-6, a device, shown as MEMS device 100, includes packaging that is at least partially open to an external environment. As shown in FIG. 3, the MEMS device 100 includes a substrate or leadframe, shown as packaging substrate 110, and a circuit, shown as circuit 120. According to an exemplary embodiment, the circuit 120 is coupled (e.g., attached, die bonded, with adhesive, etc.) to the packaging substrate 110 of the packaging of the MEMS device 100. In one embodiment, the MEMS device 100 is and/or includes a MEMS microphone. In other embodiments, the device is and/or includes an application-specific integrated circuit (ASIC) (e.g., rather than or in addition to the MEMS device 100, etc.). For example, the ASIC may be added to the MEMS device 100 next to the circuit 120 such that the ASIC is attached to a baseboard, a substrate, the packing substrate 110, etc. similar to the circuit 120 (e.g., of the MEMS microphone, etc.).

As shown in FIG. 3, the circuit 120 includes a plurality of bonds, shown as bonds 130, attached thereto. As shown in FIGS. 3 and 5-6, the bonds 130 include a pad, shown as bond pad 140, and a bond structure, shown as ball bond 150. In other embodiments, the bond structure includes a different type of bond (e.g., a stitch bond, etc.). According to an exemplary embodiment, the bond pad 140 includes a first metal or metal alloy and the ball bond 150 includes a second, dissimilar metal or metal alloy. In one embodiment, the first metal of the bond pad 140 includes aluminum or an aluminum alloy. In other embodiments, the first metal of the bond pad 140 includes gold, a gold alloy, silver, a silver alloy, copper, a copper alloy, and/or still another suitable metal or metal alloy. In one embodiment, the second, dissimilar metal of the ball bond 150 includes gold or a gold alloy. In other embodiments, the second, dissimilar metal of the ball bond 150 copper, a copper alloy, silver, a silver alloy, aluminum, an aluminum alloy, and/or still another suitable metal or metal alloy.

As shown in FIGS. 4-6, the circuit 120 includes a coating, shown as coating 170, that at least partially covers each of the bond pads 140. According to an exemplary embodiment, the coating 170 is applied at the wafer level (e.g., when a plurality of circuits 120 are arranged in a single, large sheet; prior to wire bonding rather than after wire bonding; etc.). This may allow the coating 170 to be applied in mass quantity, rather than individually at a package level (e.g., each circuit 120 individually, relative to glob tops that have to be applied at the package level, etc.). Applying the coating 170 at the wafer level rather than the package level may increase manufacturing efficiency and lower the costs of the MEMS device 100. According to an exemplary embodiment, the coating 170 is between 0.5 micrometers and 5 micrometers thick. In one embodiments, the coating 170 is 1 micrometer thick. In other embodiments, the thickness of the coating 170 can be different from these thicknesses (e.g., less than 0.5 micrometers, greater than 5 micrometers, etc.). The coating 170 is thick enough to seal portions of the bond pads 140 to protect the bond pads 140 from moisture. The material of the coating 170 may be chosen such that when compressed by a bonding action, the coating 170 elastically and/or plastically deforms without cracking. The coating 170 may thereby seal the bond pads 140 from moisture, preventing corrosion from taking place. The material of the coating 170 may additionally or alternatively be a good dielectric and/or have low ionic conduction to interrupt the electrochemical corrosion process.

In one embodiment, the coating 170 includes an elastic material such as polydimethylsiloxane (PDMS) (e.g., silicone, etc.). The PDMS may be applied using a spin coating process. In some embodiments, the PDMS is thinned with a solvent (e.g., a non-polar solvent, hexane, isooctane, etc.) prior to being spin coated onto the wafer. In another embodiment, the coating 170 includes parylene. The parylene may be applied using a vapor coating process. In alternative embodiments, another type of coating is used (e.g., another type of elastic substance, etc.). In some embodiments, the coating 170 is cured (e.g., heated in an oven for twenty minutes at one hundred and twenty degrees Celsius, etc.).

According to an exemplary embodiment, a photoresist is applied to desired portions of the coating 170 after being applied to the circuits 120 at the wafer level such that the coating 170 may be photoshaped. The desired portions of the coating 170 may include all of the coating 170 except for a central portion on each of the bond pads 140. The photoresist may be configured to resist etching at the desired portions. In some embodiments, the circuits 120 (e.g., of the wafer, etc.) are heated (e.g., cured, etc.) to remove (e.g., dry out, evaporate, etc.) a solvent of the photoresist and/or to prevent potential cracking of the photoresist. The heating process may include soft baking the wafer at a low temperature (e.g., forty degrees Celsius, between thirty and fifty degrees Celsius, etc.) for an extended period of time (e.g., ninety minutes, two hours, etc.). In some embodiments, the circuits 120 are not cured (e.g., do not undergo a baking/heating process, etc.)

As shown in FIGS. 4-6, the coating 170 defines a plurality of apertures, shown as bond holes 172. The bond holes 172 are positioned to align with each of the bond pads 140, thereby providing an exposed portion of each of the bond pads 140, shown as bond interface 160. As shown in FIG. 4, the bond holes 172 are round (e.g., to correspond with a ball bond, etc.). In other embodiments, the bond holes 172 are otherwise shaped (e.g., oblong, to correspond with another type of bond structure such as a stitch bond, etc.).

According to an exemplary embodiment, the bond holes 172 are formed in the coating 170 during an etching process at the wafer level after the photoresist is used to photoshape the coating 170. During the etching process, the portions of the coating 170 that do not include the photoresist are removed, thereby exposing the bond interfaces 160. In one embodiment, the etching process is performed using a dry etching process. For example, etching gases such as tetrafluoromethane (CF4) and/or oxygen (O2) may be used during the dry etching process (e.g., of PDMS, etc.). In an alternative embodiment, a wet etching process is used. After etching, the photoresist coating may be removed (e.g., using an ashing process, a wet strip process, etc.). The wafer including the circuits 120 may then be diced to separate the circuits 120 into individual circuits and die bonded to a respective packaging substrate 110. Therefore, the coating, heating, photoshaping, and/or etching processes may be completed at the wafer level.

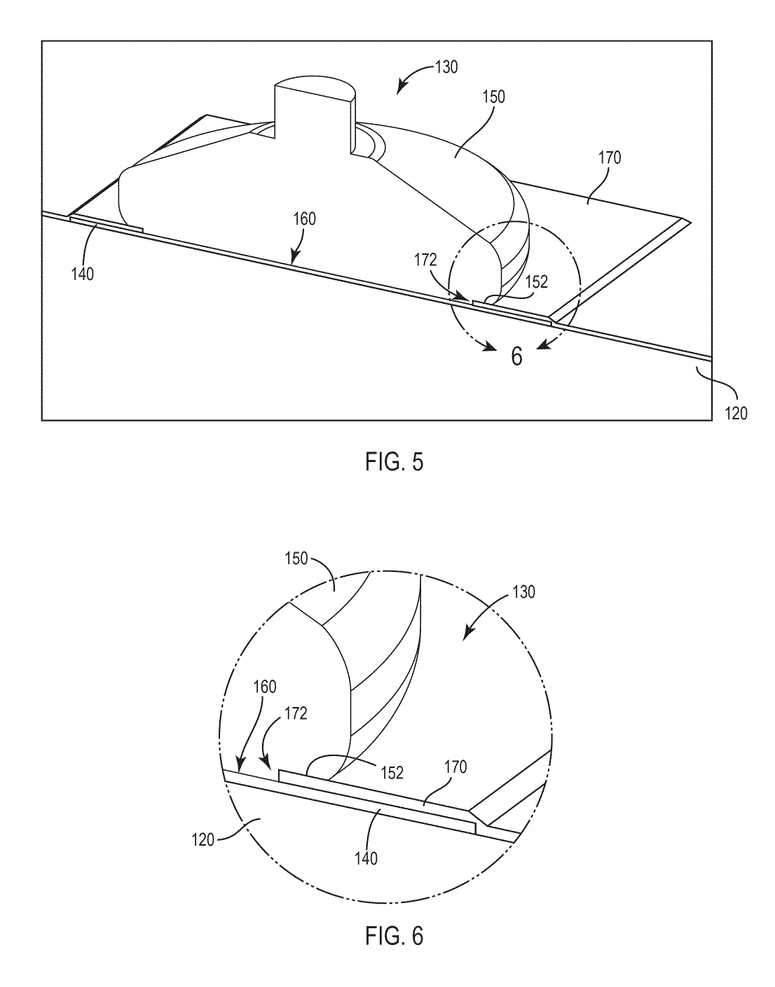

As shown in FIGS. 5-6, one of the ball bonds 150 is attached to the bond interface 160 of a respective one of the bond pads 140. According to an exemplary embodiment, the ball bonds 150 are attached to the bond interfaces 160 using an ultrasonic welding process. In other embodiments, the ball bonds 150 are otherwise coupled to the bond interfaces 160 (e.g., soldered, etc.). As shown in FIGS. 5-6, the ball bonds 150 include an edge, shown as sealing edge 152. The sealing edge 152 is configured to extend beyond the periphery of the bond hole 172 such that the sealing edge 152 at least partially overlaps the coating 170, enclosing the bond hole 172. In some embodiments, the sealing edge 152 compresses the coating 170 (e.g., the coating 170 deforms, etc.) around the periphery of the bond holes 172 during the bonding process between the ball bond 150 and the bond interface 160. Such overlap between the sealing edge 152 and the coating 170 may effectively seal the bond interface 160 and the bond pad 140 from exposure to the external environment. Enclosing the bond pads 140 with the coating 170 and the ball bonds 150 may seal the bond interface 160 from moisture, thereby preventing corrosion between the dissimilar metals of the bond pads 140 and the ball bonds 150.

According to an exemplary embodiment, the bonding process between each of the bond pads 140 and each of the ball bonds 150 is a wire bonding process that includes (i) forming the ball bond 150 from the second, dissimilar metal, (ii) bonding the ball bond 150 to the bond interface 160 of one of the bond pads 140 (e.g., using an ultrasonic scrubbing process, an ultrasonic welding process, soldering, etc.), (iii) drawing a wire out from the ball bond 150, (iv) forming a second bond structure (e.g., a stitch bond, etc.) at an end of the wire, and (v) repeat for each additional bond pad 140. The second bond structure may be attached to a bond pad of a substrate to couple the circuit 120 to the substrate. The bond pad of the substrate may include the same material as the bond pads 140, the same material as the ball bonds 150, and/or a different material than both the bond pads 140 and the ball bonds 150 (e.g., copper, gold, silver, aluminum, etc.).

According to another exemplary embodiment, the bonding process is a bump bonding process that includes (i) forming a ball bump bond from the second, dissimilar metal or metal alloy onto the bond interface 160 of each of the bond pads 140 and (ii) flip chip bonding the circuit 120 to a substrate (e.g., by one of a variety of methods including ultrasonic bonding, solder, etc.) such that the ball bump bonds interface with bond pads of the substrate. The bond pads of the substrate may include a material (e.g., a metal, a metal alloy, copper, gold, silver, aluminum, etc.) that is the same as the bond pads 140, the same as the ball bump bonds, and/or different than both the bond pads 140 and the ball bump bonds. Since the bond pads 140 are protected by the coating 170 and the bump bonds, underfill is not required for protection from moisture.

In an alternative embodiment, the coating 170 does not define the bond holes 172. By way of example, the bonding process may alternatively include wire bonding through the coating 170 without patterning with a photoresist and etching the bond holes 172. For example, the coating 170 may cover the circuit 120 and/or the bond pads 140 and wire bonds may be punched through the coating 170 to bond with the each of the bond pads 140 (e.g., without etching the bond holes 172 within the coating 170, etc.).

According to an exemplary embodiment, the MEMS device 100 including the circuit 120 provides various advantages over traditional circuits. By way of example, the bond pads 140 and the ball bonds 150 may include dissimilar metals such that a lesser amount of gold may be used, thereby reducing costs. By way of another example, the coating 170 may be applied at the wafer level, rather than using glob tops at the package level (e.g., prior to wire bonding instead of after wire bonding, etc.), thereby increasing manufacturing efficiency and reducing costs, while being compatible with complementary metal-oxide-semiconductor (CMOS) processing. By way of yet another example, the coating 170 has a relatively thin thickness (e.g., relative to glob tops, etc.) such that the coating 170 may be used in non-hermetically sealed MEMS devices (e.g., microphones, etc.) that have tight spacing (e.g., between a transducer and the bond pads 140, etc.) where glob tops cannot be used.

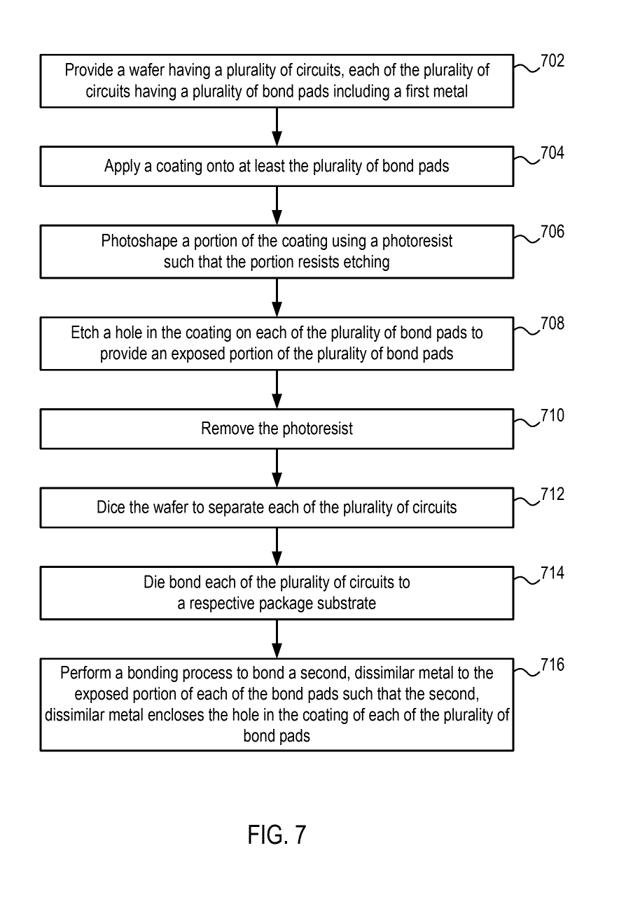

Referring now to FIG. 7, a method 700 for preventing corrosion between dissimilar bonded metals of a circuit bond interface is shown according to an example embodiment. Method 700 may be implemented with the circuit 120 and the bonds 130 of FIGS. 3-6. Accordingly, method 700 may be described with regards to FIGS. 3-6.

At step 702, a wafer having a plurality of circuits (e.g., the circuits 120, etc.) is provided. Each of the plurality of circuit may have a plurality of bond pads (e.g., the bond pads 140, etc.). The plurality of bond pads may include a first metal or metal alloy (e.g., aluminum, copper, silver, gold, etc.). According to an exemplary embodiment, the first metal includes aluminum. At step 704, a coating (e.g., the coating 170, etc.) is applied to the wafer such that at least the plurality of bond pads are covered by the coating. According to an exemplary embodiment, the coating includes an elastic material. In one embodiment, the coating includes PDMS (e.g., silicone, etc.). In such an embodiment, the PDMS may be thinned with a non-polar solvent prior to being applied to the wafer using a spin coating process. The solvent may include hexane and/or isooctane. In another embodiment, the coating includes parylene. The parylene may be applied to the wafer using a vapor coating process. In some embodiments, the coating is cured (e.g., heated in an over for twenty minutes at one hundred and twenty degrees Celsius, etc.).

At step 706, a desired portion of the coating is photoshaped using a photoresist. The desired portion of the coating may include all of the coating except for a central portion on each of the plurality of bond pads. The photoresist may be configured to resist etching at the desired portions. In some embodiments, the wafer, the coating, and the photoresist are heated (e.g., cured, etc.) to remove (e.g., dry out, evaporate, etc.) a solvent of the photoresist and to avoid cracking. The heating process may include soft baking the wafer at a low temperature (e.g., forty degrees Celsius, between thirty and fifty degrees Celsius, etc.) for an extended period of time (e.g., ninety minutes, two hours, etc.).

At step 708, a hole (e.g., the bond hole 172, etc.) is etched in the coating on each of the plurality of bond pads to provide an exposed portion (e.g., the bond interface 160, etc.) of the plurality of bond pads (e.g., the portion of the coating that does not include the photoresist is removed, etc.). In one embodiment, the etching process is performed using a dry etching process. For example, etching gases such as tetrafluoromethane (CF₄) and/or oxygen (O₂) may be used during the dry etching process (e.g., of PDMS, etc.). In an alternative embodiment, a wet etching process is used. At step 710, the photoresist of the coating is removed by any suitable process (e.g. an ashing process, a wet strip process, etc.). In some embodiments, one or more of steps 706-710 are optionally performed (e.g., where wire bonding is done straight through the coating 170 without patterning with the photoresist, etc.)

At step 712, the wafer is diced to separate each of the plurality of circuits. At step 714, each of the plurality of circuits are die bonded (e.g., coupled, attached, secured, etc.) to a respective package substrate (e.g., the packaging substrate 110, etc.) or leadframe. According to an exemplary embodiment, the respective package substrate is at least partially open to an external environment. In one embodiment, the respective package substrate is a part of a microelectromechanical system (MEMS) device. The MEMS device may include a MEMS microphone. In another embodiment, the respective package substrate is a part of an integrated circuit (e.g., an ASIC, etc.).

At step 716, a plurality of bond structures (e.g., the ball bonds 150, etc.) are bonded to the exposed portions of each of the plurality of bond pads such that the bond structures enclose the holes in the coating of each of the plurality of bond pads. The bond structures may thereby enclose the exposed portions such that the plurality of bond pads are completely sealed off from the external environment by the coating and the bonds structures. According to an exemplary embodiment, such isolation prevents corrosion between the plurality of bond pads and the plurality of bond structures. According to an exemplary embodiment, the plurality of bond structures include ball bonds for wire bonding. In other embodiments, the bond structures include ball bump bonds for bump bonding. The plurality of bond structures may include a second, dissimilar metal or metal alloy (e.g., aluminum, copper, silver, gold, etc.). According to an exemplary embodiment, the second, dissimilar metal includes gold. In other embodiments, the second, dissimilar metal includes copper.

According to an exemplary embodiment, the bonding process between the plurality of bond pads and the plurality of bond structures is a wire bonding process that includes (i) forming a bond structure (e.g., a ball bond, etc.) from the second, dissimilar metal, (ii) bonding the bond structure (e.g., using an ultrasonic scrubbing process, an ultrasonic welding process, etc.) to the exposed portion of one of the plurality of bond pads to attach the bond structure thereto, (iii) drawing a wire out from the bond structure, (iv) forming a second bond structure (e.g., a stitch bond, etc.) at an end of the wire, and (v) repeat for each additional bond pad. According to another exemplary embodiment, the bonding process is a bump bonding process that includes (i) forming a ball bump from the second, dissimilar metal onto the bond interface of each of the bond pads and (ii) flip chip bonding the circuit to a substrate (e.g., by one of a variety of methods including ultrasonic bonding, solder, etc.). According to an alternative embodiment, method 700 does not includes steps 706-710 and 716. Rather, method 700 may alternatively include punching a wire bond through the coating to bond with the each of the underlying bond pads of the circuit.

The herein described subject matter sometimes illustrates different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality, and any two components capable of being so associated can also be viewed as being “operably couplable,” to each other to achieve the desired functionality. Specific examples of operably couplable include but are not limited to physically mateable and/or physically interacting components and/or wirelessly interactable and/or wirelessly interacting components and/or logically interacting and/or logically interactable components.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.).

It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations).

Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.” Further, unless otherwise noted, the use of the words “approximate,” “about,” “around,” “substantially,” etc., mean plus or minus ten percent.

The foregoing description of illustrative embodiments has been presented for purposes of illustration and of description. It is not intended to be exhaustive or limiting with respect to the precise form disclosed, and modifications and variations are possible in light of the above teachings or may be acquired from practice of the disclosed embodiments. It is intended that the scope of the invention be defined by the claims appended hereto and their equivalents.

What is claimed is:

1. A method for preventing corrosion between dissimilar bonded metals, comprising:
providing a wafer having a plurality of circuits, each of the plurality of circuits having a plurality of bond pads including a first metal;
applying a coating onto at least the plurality of bond pads;
etching a hole in the coating on each of the plurality of bond pads to provide an exposed portion of the plurality of bond pads;
dicing the wafer to separate each of the plurality of circuits;
die bonding each of the plurality of circuits to a respective package substrate; and
performing a bonding process to bond a second, dissimilar metal to the exposed portion of each of the plurality of bond pads such that the second, dissimilar metal encloses the hole in the coating of each of the plurality of bond pads, thereby enclosing the exposed portion.

2. The method of claim 1, wherein at least one of the first metal and the second, dissimilar metal include at least one of aluminum, gold, copper, and silver.

3. The method of claim 2, wherein the first metal includes aluminum and the second, dissimilar metal includes gold.

4. The method of claim 2, wherein the first metal includes aluminum and the second, dissimilar metal includes copper.

5. The method of claim 1, wherein the coating includes an elastic material, the elastic material including at least one of parylene and polydimethylsiloxane.

6. The method of claim 1, further comprising thinning the coating with a solvent including at least one of hexane and isooctane prior to applying the coating.

7. The method of claim 1, wherein the coating is applied using at least one of a spin coating process and a vapor coating process.

8. The method of claim 1, further comprising photoshaping a portion of the coating using a photoresist such that the portion resists the etching.

9. The method of claim 8, further comprising heating the wafer and the coating at a low temperature for a period of time to dry out a solvent of the photoresist.

10. The method of claim 1, wherein etching the hole in the coating of each of the plurality of bond pads is performed using a dry etching process.

11. The method of claim 1, wherein the bonding process includes at least one of a wire bonding process and a bump bonding process.

12. The method of claim 11, wherein performing the wire bonding process includes:
forming a bond structure from the second, dissimilar metal, wherein the bond structure includes a ball bond;
ultrasonically scrubbing the bond structure onto the exposed portion of one of the plurality of bond pads to attach the bond structure thereto;
drawing a wire out from the bond structure; and
forming a second bond structure at an end of the wire, wherein the second bond structure includes a stitch bond.

13. The method of claim 1, wherein the respective package substrate is at least partially open to an external environment, and wherein the plurality of bond pads are completely sealed off from the external environment by the coating and the second, dissimilar metal.

14. A circuit for a device having packaging that is at least partially open to an external environment, comprising:
a plurality of bond pads including a first metal;
a coating at least partially covering each of the plurality of bond pads, the coating defining a plurality of holes, one of the plurality of holes positioned to align with each of the plurality of bond pads, thereby providing an exposed portion of each of the plurality of bond pads; and
a plurality of bond structures including a second, dissimilar metal, each of the plurality of bond structures attached to the exposed portion of a respective one of the plurality of bond pads such that the plurality of bond structures enclose the plurality of holes in the coating, thereby enclosing the exposed portion of each of the plurality of bond pads such that the plurality of bond pads are completely sealed off from the external environment by the coating and the plurality of bond structures.

15. The circuit of claim 14, wherein the first metal includes aluminum and the second, dissimilar metal includes at least one of gold and copper.

16. The circuit of claim 14, wherein the coating includes at least one of parylene and polydimethylsiloxane.

17. The circuit of claim 14, wherein the plurality of holes in the coating are formed using a photoshaping and etching process after the coating is applied to at least the plurality of bond pads, and wherein each of the plurality of bond structures are attached to the exposed portion of one of the plurality of bond pads using an ultrasonic welding process after the photoshaping and etching process.

18. The circuit of claim 14, wherein the plurality of bond structures include a sealing edge configured to extend beyond a periphery of the plurality of holes such that the sealing edge at least partially overlaps the coating.

19. A device, comprising:
a packaging at least partially open to an external environment; and
a circuit die bonded to a packaging substrate of the packaging, the circuit including:
a plurality of bond pads including a first metal;
a coating at least partially covering each of the plurality of bond pads, the coating defining a plurality of holes, one of the plurality of holes positioned to align with each of the plurality of bond pads, thereby providing an exposed portion of each of the plurality of bond pads; and
a plurality of bond structures including a second, dissimilar metal, each of the plurality of bond structures attached to the exposed portion of a respective one of the plurality of bond pads such that the plurality of bond structures enclose the plurality of holes in the coating, thereby enclosing the exposed portion of each of the plurality of bond pads such that the plurality of bond pads are completely sealed off from the external environment by the coating and the plurality of bond structures.

20. The device of claim 19, wherein the device includes a microelectromechanical system (MEMS) device, and wherein the MEMS device includes a microphone.
